(19) United States
(12) Patent Application Publication
(10) Pub. No.: US 2021/0249520 A1
(43) Pub. Date: Aug. 12, 2021

(54) MULTIPLE GATE SIDEWALL SPACER WIDTHS

(71) Applicant: Nicolas PONS, Corbeil-Essonnes (FR)

(72) Inventor: Nicolas PONS, Corbeil-Essonnes (FR)

(73) Assignee: X-FAB France SAS, Corbeil-Essonnes (FR)

(21) Appl. No.: 17/168,430

(22) Filed: Feb. 5, 2021

(30) Foreign Application Priority Data
Feb. 6, 2020 (GB) 2001636.6

(51) Int. Cl. H01L 29/66; H01L 21/02; H01L 21/8234; H01L 21/3065

(52) U.S. Cl. CPC H01L 29/6656; H01L 21/02274; H01L 21/3065; H01L 21/02252; H01L 21/823468

(57) ABSTRACT

A method of forming gate sidewall spacers of two different widths, the method including providing a semiconductor substrate and providing a first and second gate structure on the semiconductor substrate. Each gate structure has at least one sidewall. The method includes blanket depositing, on said first and second gate structures, a first nitride layer and anisotropically etching the first nitride layer leaving at least some of said first nitride layer on at least one sidewall of each gate structure so as to form a first nitride sidewall spacer portion on each gate structure. The method further includes removing the first sidewall spacer portion from the first gate structure, blanket depositing, on said first and second gate structures, a second nitride layer, and anisotropically etching the second nitride layer leaving at least some of said second nitride layer on at least one sidewall of each gate structure so as to form a second nitride sidewall spacer portion on each gate structure.

This application claims priority to United Kingdom Patent Application No. 2001636.6, filed on Feb. 6, 2020, the entire contents of which are hereby incorporated by reference.

### TECHNICAL FIELD

The present invention relates to semiconductor device fabrication methods, and in particular, to a method for forming gate sidewall spacers having different widths.

### BACKGROUND

The width of a sidewall spacer formed adjacent a gate structure is an important variable in semiconductor manufacture. The width of the sidewall spacer determines the distance between the source/drain implants and the gate, and thus, the electric field between them. Therefore, for a semiconductor device with multiple transistors having different operating voltages, it may be desirable to create multiple different sidewall spacer widths.

Typically, in existing methods, gate sidewall spacers are formed by isotropic deposition of one or more the insulating layers over a gate structure, followed by the anisotropic etching of said layers. As such, the final spacer width depends on the thickness of the deposited layers.

For example, U.S. Pat. No. 6,316,304 discloses a method to form two different spacer widths by (a) removing an oxide layer over a first gate structure not protected by a photoresist, (b) blanket depositing a further oxide layer, (c) anisotropically dry etching the combined oxide layer, and (d) further anistropically dry etching over the second gate structure. As a result, the sidewall spacer is wider on the second gate structure than the first gate structure. However, the anisotropic oxide etch time is increased due to the increased oxide layer thickness. Furthermore, there is a risk that oxide layer could be completely removed, leading to very small spacers.

Similarly, U.S. Pat. No. 7,011,929 discloses a method of forming spacers of N different widths on the same chip by first stacking N+1 insulator layers, then successively protecting a given area with photoresist and removing the insulator layers from the remaining unprotected area. In order to form two different spacer widths (N=2), three insulating layers are deposited. The two different spacers are formed by (a) a first anisotropic etching of the uppermost layer, (b) removing the uppermost layer over a first gate structure not protected by a photoresist, (c) a second anisotropic etching through the thickness of the next two layers. Like U.S. Pat. No. 6,316,304, the anisotropic oxide etch time is increased due to the increased insulating layer thickness, and the risk exists that the uppermost layer(s) may be removed completely, leading to very small spacers.

In light of the above, there may be a need for a method of creating at least two different sidewall spacer widths with a low etching time and sufficient spacer width.

### SUMMARY

According to a first aspect there is provided a method of forming gate sidewall spacers of two different widths as set out in the accompanying claims.

According to a second aspect there is provided a semiconductor device.

Certain embodiments of the invention will now be described, by way of example only, with reference to the accompanying drawings.

### BRIEF DESCRIPTION OF THE DRAWINGS

FIG. 1A is a cross-sectional view of a portion of a semiconductor device at a manufacturing stage according to an embodiment;

FIG. 1B is a cross-sectional view of a portion of a semiconductor device at a manufacturing stage according to an embodiment;

FIG. 1C is a cross-sectional view of a portion of a semiconductor device at a manufacturing stage according to an embodiment;

FIG. 1D is a cross-sectional view of a portion of a semiconductor device at a manufacturing stage according to an embodiment;

FIG. 1E is a cross-sectional view of a portion of a semiconductor device at a manufacturing stage according to an embodiment;

FIG. 1F is a cross-sectional view of a portion of a semiconductor device at a manufacturing stage according to an embodiment;

FIG. 1G is a cross-sectional view of a portion of a semiconductor device at a manufacturing stage according to an embodiment;

FIG. 1H is a cross-sectional view of a portion of a semiconductor device at a manufacturing stage according to an embodiment;

FIG. 1I is a cross-sectional view of a portion of a semiconductor device at a manufacturing stage according to an embodiment;

FIG. 2A is a cross-sectional view of a portion of a semiconductor device at a manufacturing stage according to an alternative embodiment;

FIG. 2B is a cross-sectional view of a portion of a semiconductor device at a manufacturing stage according to an alternative embodiment;

FIG. 2C is a cross-sectional view of a portion of a semiconductor device at a manufacturing stage according to an alternative embodiment;

FIG. 2D is a cross-sectional view of a portion of a semiconductor device at a manufacturing stage according to an alternative embodiment;

FIG. 2E is a cross-sectional view of a portion of a semiconductor device at a manufacturing stage according to an alternative embodiment;

FIG. 3A is a cross-sectional view of a portion of a semiconductor device at a manufacturing stage according to an alternative embodiment;

FIG. 3B is a cross-sectional view of a portion of a semiconductor device at a manufacturing stage according to an alternative embodiment; and

FIG. 4 is a flow diagram of a method according to an embodiment.

### DETAILED DESCRIPTION

Embodiments described herein provide a method of forming gate sidewall spacers of two different widths. The method begins with providing a semiconductor substrate 10. The substrate 10 may comprise silicon or silicon on insulator (SOI) wafer.

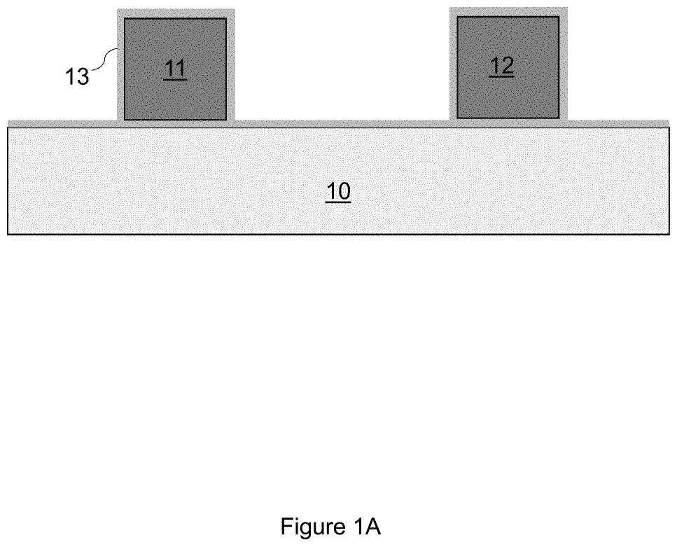

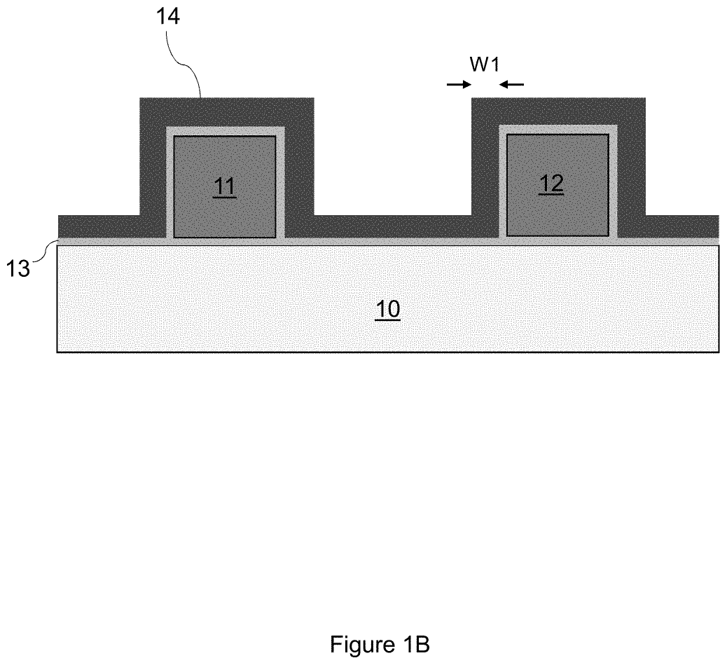

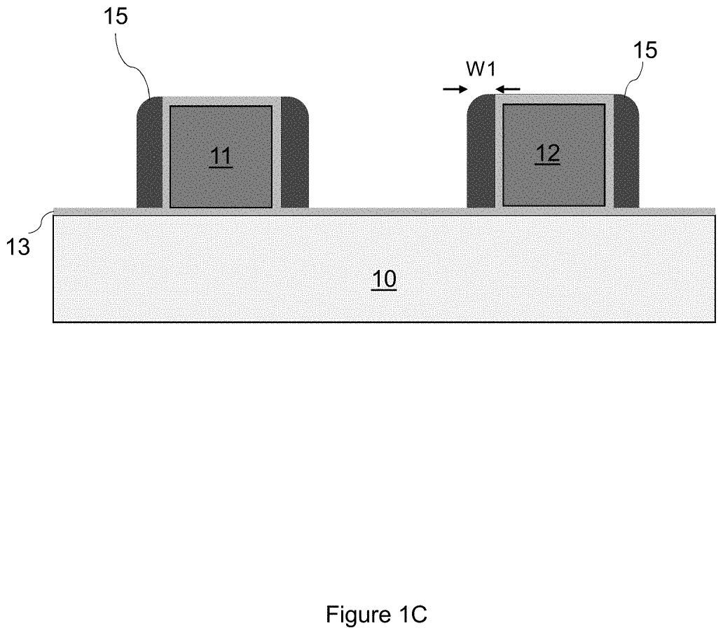

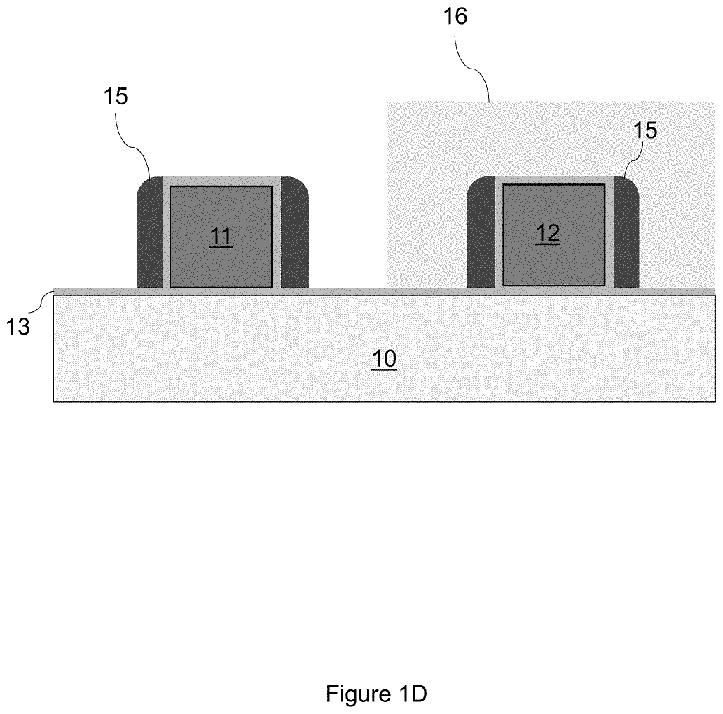

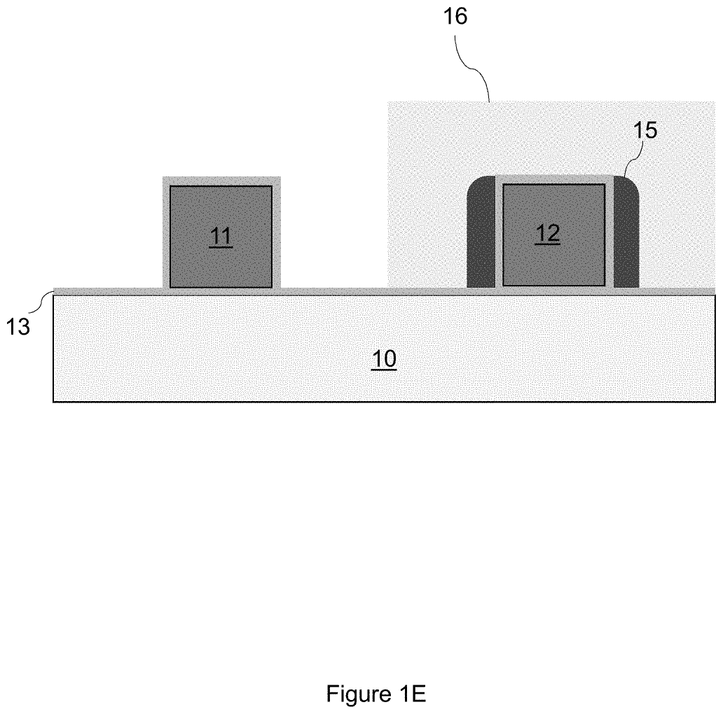

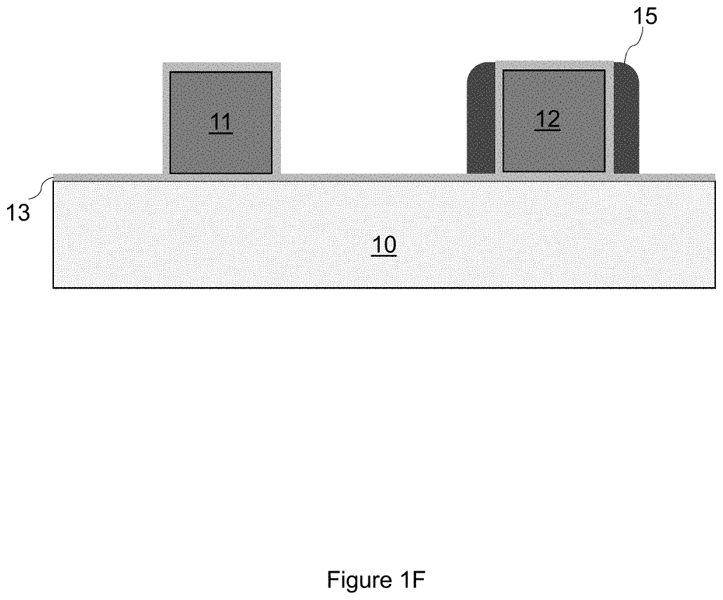

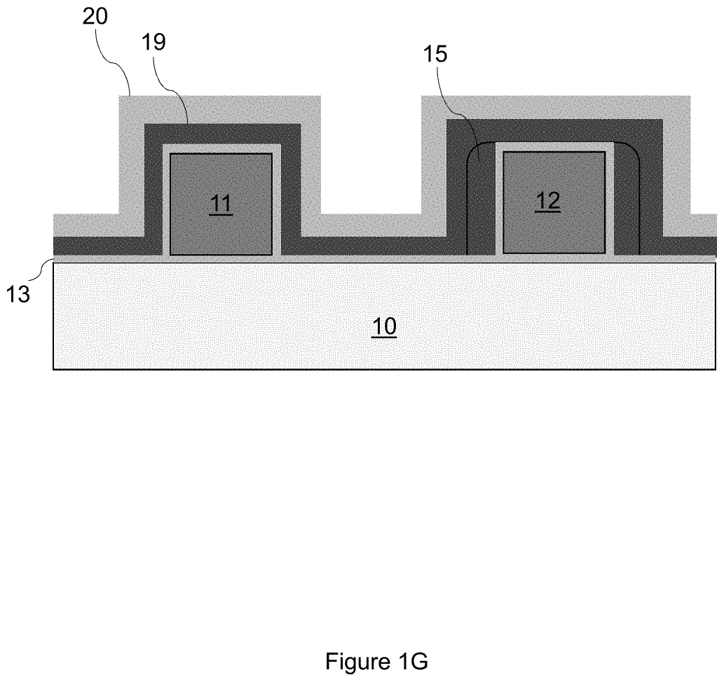

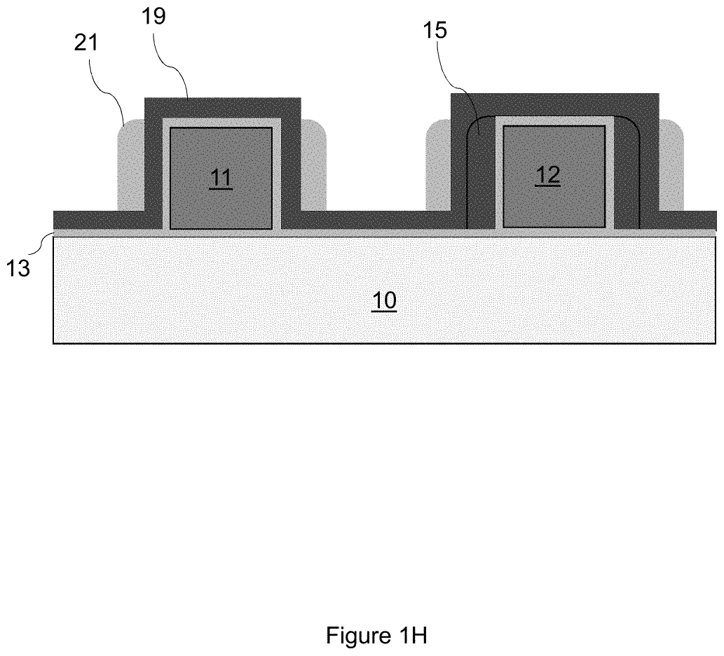

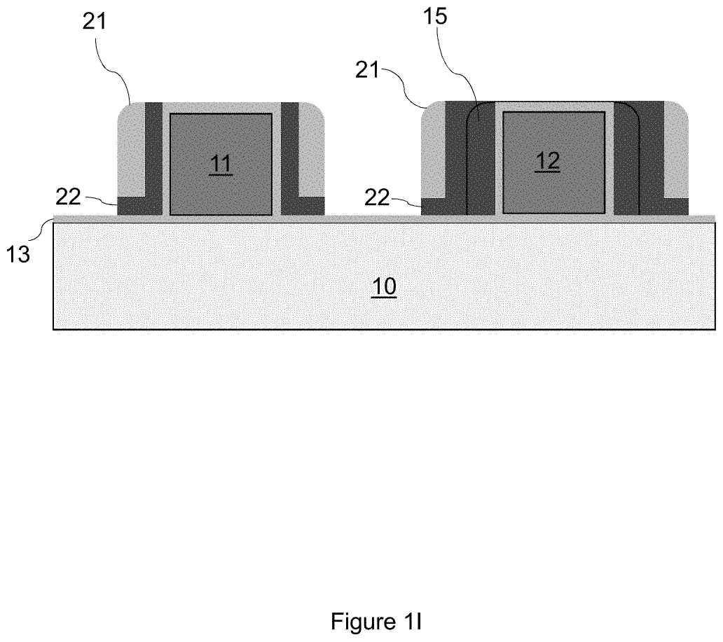

In the example shown in FIG. 1A, a first gate structure 11 and a second gate structure 12 are provided on the semiconductor substrate 10. The first and second gate structures 11, 12 extend to substantially the same height above the substrate 10, but may support devices having different operating voltage requirements. By way of example, the first gate structure 11 may support a 1.25 V device, whereas the second gate structure may support a 5 V device. As such, the second gate structure 12 requires a thicker sidewall spacer width to reduce the electric field between source and drain. The gate structures 11, 12 may be composed of any suitable conductive gate material, such as polysilicon, a metal nitride (e.g. titanium nitride, TiN) or silicon-germanium (SiGe). Various methods for providing the gate structures 11, 12 are known in the art and are suitable for use herein. Typically, such methods include providing one or more gate oxide layers formed over the substrate 10, followed by a conductive gate material layer, followed by a photolithographic patterning and plasma etching to form the gate structures. In some embodiments, the gate oxide layer underlying the second gate structure 12 is thicker than the gate oxide layer underlying the first gate structure 11. Then, after providing the gate structures 11, 12, an oxidation step is performed to form a silicon oxide layer 13 exposed gate structure 11, 12 surfaces, and to increase the gate oxide layer thickness on the areas of the substrate 10 not underlying the gate structures 11, 12.

In the next step of the method, a first nitride layer 14 is blanket deposited on the gate structures 11, 12, as shown in FIG. 1B. The first nitride layer 14 has a substantially uniform thickness W1, forming a “blanket” overlying the gate structures 11, 12 and the exposed portions of the substrate 10. Typically, the thickness W1 is in the range of 50 to 500 Angstroms, for example, approximately 300 Angstroms. It will be seen from the following description that the thickness W1 of this initial nitride layer determines the final difference in thicknesses between the sidewall spacers on the first and second gate structures 11, 12. In some embodiments, the first nitride layer is deposited by rapid thermal chemical vapor deposition (RTCVD), low-pressure chemical vapor deposition (LPCVD) or pressure-enhanced chemical vapor deposition (PECVD).

Referring to FIG. 1C, the nitride layer 14 is anisotropically etched to leave at least some of the first nitride layer 14 the sidewalls of each gate structure 11, 12, so as to form a first sidewall spacer portion 15 on each gate structure. The etching process may be a dry etch with good nitride selectivity, for example plasma etching with a SF₆/CH₂F₂/N₂ or CH₃F/O₂ etchant. Endpoint detection is determined when the nitride layer 14 overlying the top of gate structures 11, 12 has been removed. In this way, a spacer portion 15 of the nitride remains on the sidewalls of each gate structure 11, 12, while the tops of the gate structures 11, 12 are exposed. At this point, the sidewall spacer portions 15 across both the first and second gate structures 11, 12 are substantially of equal width W1.

Next, the first sidewall spacer portion is removed from the first gate structure 11. In some embodiments, this is achieved by patterning a region over the second gate structure with a photoresist 16, as shown in FIG. 1D. In this way, the photoresist 16 forms a protective layer over the second gate structure 12, while leaving the first gate structure 11 exposed. The photoresist region 16 may be formed via photolithographic patterning. Referring to FIG. 1E, an isotropic etch is performed to remove the first sidewall spacer portions 15 from the first gate structure 11. Under the photoresist 16, the sidewall spacer portions 15 on the second gate structure 12 remain intact. The etch may be an isotropic dry etch with a very good nitride to oxide selectivity (e.g. >10:1), and usable with the photoresist 16. It will be appreciated that the particular isotropic etch process will depend on the composition of the nitride. For instance, a HBr/SF₆ chemistry dry etch may be used. In any case, the nitride sidewall spacer portions 15 are stripped from the first gate structure 11.

Next, the photoresist 16 is removed, as shown in FIG. 1F. As such, the first sidewall spacer portions 15 are removed from the first gate structure 11, while they remain intact second gate structure 12 remain intact.

Referring to FIG. 1G, a second nitride layer 19 is blanket deposited, followed by blanket deposition of an oxide layer 20. As above, RTCVD, LPCVD or PECVD may be used to deposit the second nitride layer 19 and/or the oxide layer 20. For example, the nitride 19 deposition may be done by RTCVD and the oxide 20 deposition by PECVD. The thickness of both the second nitride layer 19 and the oxide layer 20 are in the range of 50 to 1000 Angstroms. For example, the second nitride layer 19 may in one case have a thickness of approximately 240 Angstroms, whereas the oxide layer 20 has a thickness of approximately 560 Angstroms.

Next, as shown in FIG. 1H, the oxide layer 20 is anisotropically etched, leaving at least some of said oxide layer 20 so as to form an oxide sidewall spacer portion 21 on each gate structure 11, 12 sidewall. The etch may be a dry etch, with good oxide to nitride selectivity (e.g. >10:1), such as a plasma etching using C₄F₈/Ar/O₂, C₄F₆/Ar/O₂ or CF₄/O₂/Ar.

Finally, as shown in FIG. 1I, the oxide etch is followed by an anisotropic etch of the second nitride layer 19. As above, the etch at this stage may be a dry etch with a good nitride to oxide selectivity (e.g. >10:1), such as a plasma etching using SF₆/CH₂F₂/N₂ or CH₃F/O₂. The remaining portions of the second nitride layer 19 form L-shaped sidewall spacer portions 22. While FIG. 1I shows defined lines separating the first spacer portions 15, and the L shaped portions 22, it should be understood that, in reality, the two nitride layers may not be distinguishable if the same type of nitride is used for each layer. The point is that the width of the sidewall spacer formed on the second gate structure 12 is greater than the width of the spacer on the first gate structure 11.

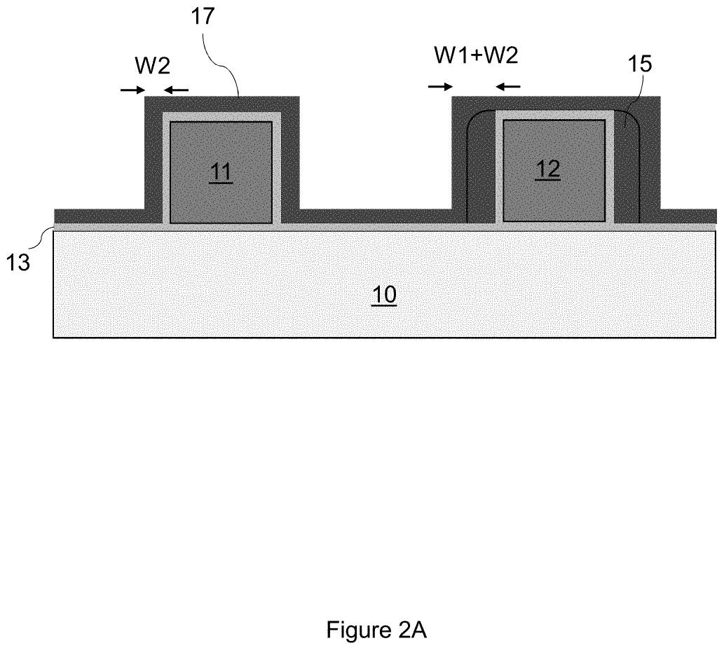

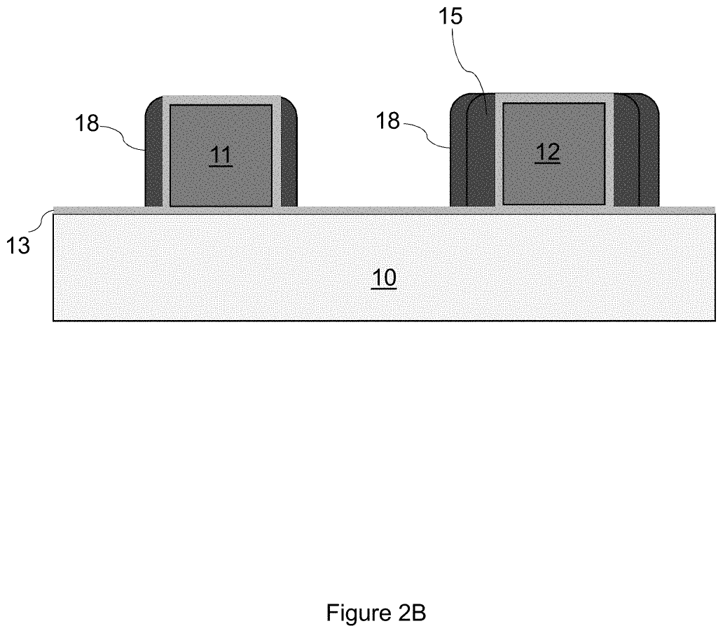

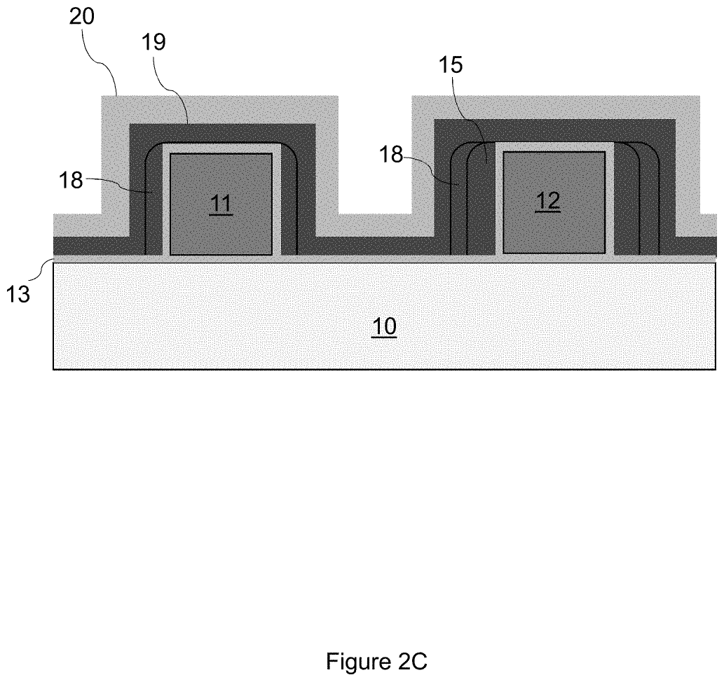

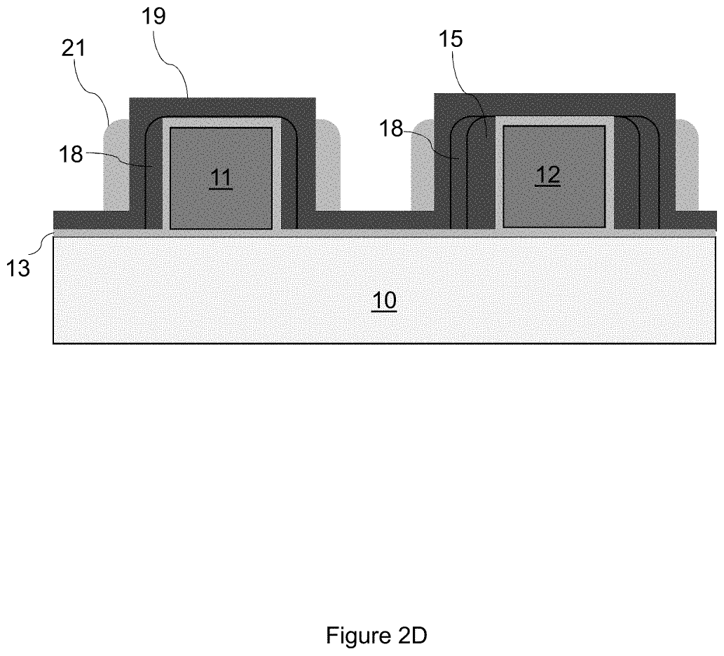

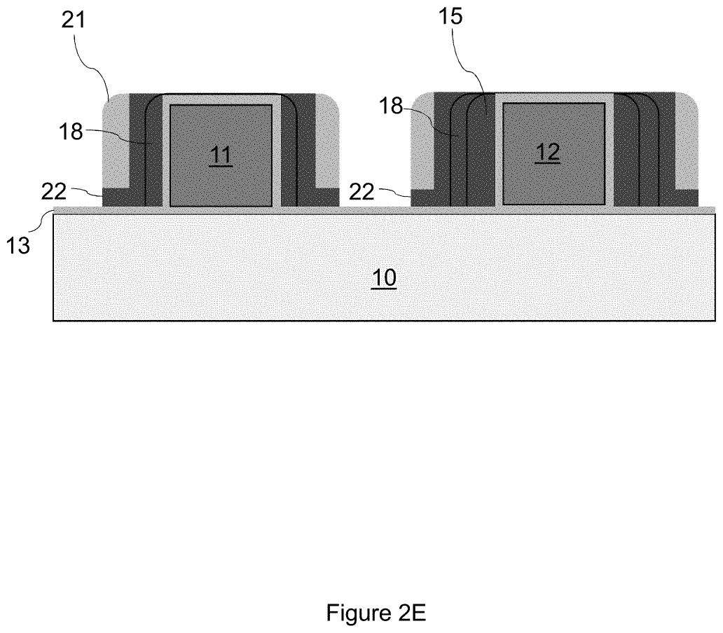

FIGS. 2A to 2E illustrate an alternative embodiment, wherein an additional nitride I-shaped spacer portion 18 is provided on each gate structure. In this case, the same steps of the method as described in connection with FIGS. 1A to 1F are performed, as above. Then, as illustrated in FIG. 2A, a third nitride layer 17 is deposited. The thickness W2 of the third nitride layer 17 is typically in the range of 50 to 1000 Angstroms, and may, for example, in one case have a thickness of approximately 80 Angstroms. After deposition, the third nitride layer 17 is anisotropically etched, leaving at least some of said third nitride layer 17 on the sidewall of each gate structure 11, 12 so as to form a second sidewall spacer portion 18 on each gate structure 11, 12 sidewall, as shown in FIG. 2B. Endpoint detection is determined when the nitride layer 17 overlying the top of gate structures 11, 12 is removed. In this way, a further spacer portion 18 of the nitride remains on the sidewalls of each gate structure 11, 12, while the tops of the gate structures 11, 12 are exposed. As a result, the second gate structure 12 is provided with sidewall spacers having a thickness of the first 15 and second 18 sidewall spacer portions combined. As discussed above in connection with FIG. 1C, the etching process used may be a suitable dry etch with good nitride selectivity. Advantageously, if P-type lightly doped drain (PLDD) implants are formed in the substrate 10, the extra width W2 reduces the overlap of the PLDD implant with the gate, mitigating the problem of boron diffusion.

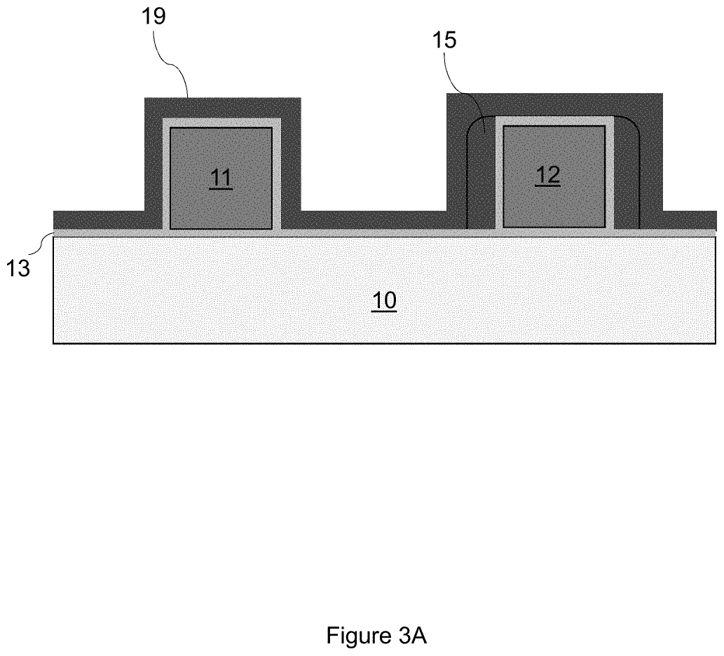

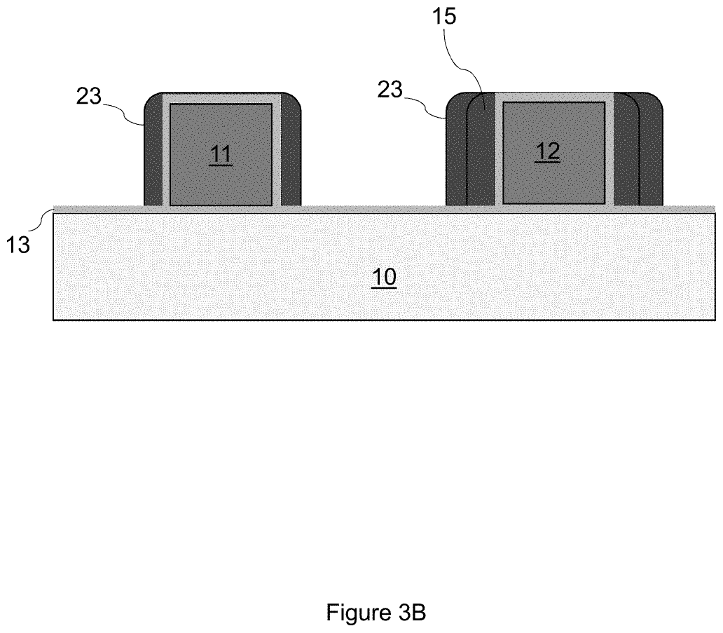

As with FIGS. 1G and 1H, the method continues with depositing the second nitride layer 19 and oxide layer 20, as shown in FIG. 2C, and anisotropically etching the oxide layer 20, as shown in FIG. 2D. After etching, at least some of said oxide layer 20 is left so as to form an oxide sidewall spacer portion 21 on each gate structure 11, 12 sidewall. Finally, as illustrated in FIG. 2E, the oxide etch is followed by an anisotropic etch of the second nitride layer 19. The etch at this stage may be a dry etch with a good nitride to oxide selectivity (e.g. >10:1). As described above, the remaining portions of the second nitride layer 19 form L-shaped sidewall spacer portions 22. While FIG. 2E shows defined lines separating the first spacer portions 15, second spacer portions 18, and the L-shaped portions 22, it should be understood that, in reality, the three nitride layers may not be distinguishable. The point is that the width of the sidewall spacer formed on the second gate structure 12 is greater than the width of the spacer on the first gate structure 11, and, in this case, an additional spacer width W2 is provided on both gate structures 11, 12. FIGS. 3A and 3B illustrate a further alternative embodiment, wherein the same steps of the method as described in connection with FIGS. 1A to 1F are first performed, as above. Then, as shown in FIG. 3A, a second nitride layer 19 is blanket deposited. In this embodiment, an oxide layer is not deposited at this stage (in contrast to FIG. 1G). Next, as shown in FIG. 3B, the second nitride layer 19 is etched, using a dry etch with a good nitride to oxide selectivity (e.g. >10:1). The remaining portions of the second nitride layer 19 form I-shaped sidewall spacer portions 23. While FIG. 3B shows defined lines separating the first spacer portions 15, and the I-shaped portions 23, it should be understood that, in reality, the two nitride layers may not be distinguishable. The point is that the width of the sidewall spacer formed on the second gate structure 12 is greater than the width of the spacer on the first gate structure 11.

While the above methods have been described in connection with a substrate 10 having two different gate structures 11, 12, in some embodiments, a plurality of different gate structures are provided, having N different sidewall spacer widths. In this case, the steps of the method as described in connection with FIGS. 1B to 1F are repeated N−1 times. Taking the first gate as the gate with the smallest sidewall spacer width and the Nth gate as the gate with the largest sidewall spacer width, then, in the first iteration of the steps of FIGS. 1B-F the first gate is the only gate not protected by photoresist. In the second iteration, the first and second gates are not protected by photoresist, while the third to N^{th} gates are protected. Finally, in the last iteration, only the N^{th} gate is protected by the photoresist, while all of the remaining gates (i.e. first to N−1^{th}) are exposed. It can be seen that, by repeating the method steps as described in connection with FIGS. 1B to 1F a total of N−1 times, N different widths of sidewall spacer are formed.

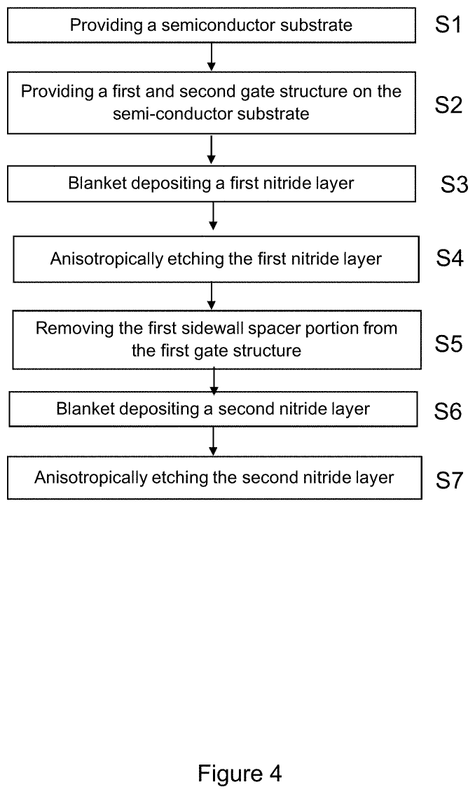

FIG. 4 is a flow diagram of the method described above according to an embodiment of the invention. The method comprises providing a semiconductor substrate (step S1), providing a first and second gate structure on the semiconductor substrate, each gate structure having at least one sidewall (step S2), and blanket depositing, on said first and second gate structures, a first nitride layer (step S3). The method further comprises anisotropically etching the first nitride layer leaving at least some of said first nitride layer on at least one sidewall of each gate structure so as to form a first nitride sidewall spacer portion on each gate structure (step S4); removing the first sidewall spacer portion from the first gate structure (step S5); and blanket depositing, on said first and second gate structures, a second nitride layer (step S6). The method further comprises anisotropically etching the second nitride layer, leaving at least some of said second nitride layer on said at least one sidewall of each gate structure so as to form a second nitride sidewall spacer portion on each gate structure (step S7).

While specific embodiments of the invention have been described above, it will be appreciated that the invention may be practiced otherwise than as described. The descriptions above are intended to be illustrative, not limiting. It will be apparent to one skilled in the art that modifications may be made to the invention as described without departing from the scope of the claims set out below.

Each feature disclosed or illustrated in the present specification may be incorporated in the invention, whether alone or in any appropriate combination with any other feature disclosed or illustrated herein.

What is claimed is:

1. A method of forming gate sidewall spacers of two different widths, the method comprising:
providing a semiconductor substrate;
providing a first and second gate structure on the semiconductor substrate, each gate structure having at least one sidewall;
blanket depositing, on said first and second gate structures, a first nitride layer;
anisotropically etching the first nitride layer leaving at least some of said first nitride layer on at least one sidewall of each gate structure so as to form a first nitride sidewall spacer portion on each gate structure;
removing the first sidewall spacer portion from the first gate structure;
blanket depositing, on said first and second gate structures, a second nitride layer; and
anisotropically etching the second nitride layer leaving at least some of said second nitride layer on at least one sidewall of each gate structure so as to form a second nitride sidewall spacer portion on each gate structure.

2. The method of claim 1, wherein before said step of blanket depositing, on said first and second gate structures, a second nitride layer, the method further comprises:
blanket depositing, on said first and second gate structures, a third nitride layer; and
anisotropically etching the third nitride layer, leaving at least some of said third nitride layer on said at least one sidewall of each gate structure so as to form a third nitride sidewall spacer portion on each gate structure.

3. The method of claim 1, wherein after said step of blanket depositing, on said first and second gate structures, a second nitride layer, the method further comprises:
blanket depositing, on said first and second gate structure, an oxide layer; and
anisotropically etching the oxide layer, leaving at least some of said oxide layer on said at least one sidewall of each gate structure, so as to form an oxide sidewall spacer portion on each gate structure.

4. The method of claim 1, wherein removing the first sidewall spacer portion from the first gate structure comprises:
patterning a region over the second gate structure with a photoresist;
performing an isotropic etching to remove the first sidewall spacer portion from the first gate structure; and
removing the photoresist.

5. The method of claim 4, wherein performing an isotropic etching to remove the first sidewall spacer portions from the first gate structure comprises performing a dry etching using a HBr/SF₆ chemistry.

6. The method of claim 1, wherein after said step of providing the first and second gate structure on the semiconductor substrate, the method further comprises performing an oxidation step to form a silicon oxide layer on said first and second gate structures.

7. The method of claim 1, wherein each of the first nitride layer and second nitride layer is deposited by rapid thermal chemical vapor deposition (RTCVD), low-pressure chemical vapor deposition (LPCVD) or pressure-enhanced chemical vapor deposition (PECVD).

8. The method of claim 1, wherein the first nitride layer has a thickness in the range of 50 Angstroms to 500 Angstroms.

9. The method of claim 1, wherein the second nitride layer has a thickness in the range of 50 Angstroms to 1000 Angstroms.

10. The method of claim 2, wherein the third nitride layer has a thickness in the range of 50 Angstroms to 1000 Angstroms.

11. The method of claim 3, wherein the oxide layer has a thickness of in the range of 50 Angstroms to 1000 Angstroms.

12. The method of claim 1, wherein anisotropically etching each of the first or second nitride layer comprises performing a SF₆/CH₂F₂/N₂ or CH₃F/O₂ plasma etch.

13. The method of claim 3, wherein anisotropically etching the oxide layer comprises performing a C₄F₈/Ar/O₂, C₄F₆/Ar/O₂ or CF₄/O₂/Ar plasma etch.

14. The method of claim 1, wherein each of the first and second gate structures has at least two sidewalls.

15. A semiconductor device comprising:
a semiconductor substrate;
a first gate structure on said semiconductor substrate, having at least a first sidewall;
a second gate structure on said semiconductor substrate, having at least a second sidewall;
a first sidewall spacer on said first sidewall; and
a second sidewall spacer on said second sidewall;
wherein said second sidewall spacer comprises:
first and second nitride layers adjacent said second sidewall; and
said first sidewall spacer comprises:
said second nitride layer adjacent said first sidewall.

16. The semiconductor device of claim 15, wherein each of the first and second gate structures has at least two sidewalls.

17. The semiconductor device of claim 15, wherein said first nitride layer forms an I-shaped nitride spacer, and wherein said second nitride layer forms an L-shaped spacer, and wherein said first and second sidewall spacers further comprise an I-shaped oxide spacer on said second nitride layer.

18. The semiconductor device of claim 15, wherein said first sidewall spacer further comprises a third nitride layer forming an I-shaped nitride spacer between said first sidewall and said second nitride layer, and wherein said second sidewall spacer further comprises said third nitride layer forming an I-shaped nitride spacer between said first nitride layer and said second nitride layer.

19. The semiconductor device of claim 15, wherein said first and second nitride layers form I-shaped nitride spacers.

20. The semiconductor device of claim 15, wherein each of the first and second gate structures comprises: polysilicon, silicon-germanium (SiGe) or titanium nitride (TiN).

21. The semiconductor device of claim 15, wherein the each of the nitride layers comprises: silicon nitride (Si₃N₄) or silicon oxynitride (SiOₓN_{y}).

22. The semiconductor device of claim 17, wherein the oxide spacer comprises: silicon dioxide (SiO₂) or silicon oxynitride (SiOₓN_{y}).

23. A method of forming gate sidewall spacers of multiple different widths, the method comprising:
(a) providing a semiconductor substrate;
(b) providing N gate structures on the semiconductor substrate, each gate structure having at least one sidewall, wherein N is at least two;
(c) blanket depositing, on said N gate structures, a nitride layer;
(d) anisotropically etching the nitride layer leaving at least some of nitride layer on at least one sidewall of each of the N gate structures so as to form a nitride sidewall spacer portion on each gate structure; and
(e) removing the nitride sidewall spacer portions from a first group of the N gate structures and not from a second group of the N gate structures;
wherein steps (c) to (e) are repeated at least once, and wherein in each repetition of steps (c) to (e), the first group of the N gate structures includes at least one additional gate structure from the second group of the N gate structures.
